(19) United States
(12) Patent Application Publication
(10) Pub. No.: US 2012/0236230 A1
(43) Pub. Date: Sep. 20, 2012

(54) DEVICE SUBSTRATE AND METHOD FOR MANUFACTURING SAME

(75) Inventors: Hiroki Nakahama, Osaka (JP); Takashi Matsui, Osaka (JP); Takeshi Horiguchi, Osaka (JP); Motoji Shiota, Osaka (JP)

(73) Assignee: SHARP KABUSHIKI KAISHA, Osaka (JP)

(21) Appl. No.: 13/510,721

(22) PCT Filed: Sep. 15, 2010
(86) PCT No.: PCT/JP2010/065980

§ 371 Date: Jun. 6, 2012

(30) Foreign Application Priority Data
Nov. 20, 2009 (JP) 2009-264613

(51) Int. Cl. G02F 1/1335; H01J 9/00; H05K 13/04; H05K 1/18

(52) U.S. Cl. 349/62; 361/748; 445/24; 156/60; 156/278

(57) ABSTRACT

Disclosed is a device substrate wherein an insulating layer (60) having a terminal (24) formed on the surface thereof is formed over the entire surface of a glass substrate (20), excluding a display section, and therefore, the border (outer periphery) of the insulating layer (60) does not approach a region where an NCF (81) is provided, i.e., an area close to an LSI chip (40). This prevents the insulating layer (60) from being peeled off from the border thereof by the NCF (81), and thereby prevents the terminal (24) from breaking. Furthermore, the terminal (24) and a bump electrode (40a) are permanently pressure-bonded to each other by the elasticity of the insulating layer (60), and a stable electrical connection therebetween can be ensured.

### TECHNICAL FIELD

The present invention relates to a device substrate such as a display panel and to a method for manufacturing the device substrate. More particularly, the present invention relates to a device substrate including terminals that are pressure-bonded to terminals of an electronic part such as an LSI chip mounted using an adhesive agent, and to a method for manufacturing the device substrate.

### BACKGROUND ART

Traditionally, in mounting an electronic part on a glass substrate or the like, an anisotropic conductive film (hereinafter referred to as “ACF”) may be used. FIG. 21 is a schematic plan view of a conventional liquid crystal panel 600 used for a mobile phone or the like that has electronic parts mounted by using this ACF.

As shown in FIG. 21, the liquid crystal display panel 600 includes two glass substrates 610 and 615 disposed facing each other, an LSI chip 630, and an FPC substrate 640. The liquid crystal panel referred to in the present specification described below includes two glass substrates that are disposed facing each other and electronic parts such as an LSI chip that are mounted on the glass substrate, and does not include a backlight, a polarizing plate and the like. However, the liquid crystal panel of the present specification is not limited to such, and does not necessarily have to include electronic parts such as an FPC substrate.

In a space between the two glass substrates 610 and 615, liquid crystal (not shown in the figure) is sealed by a sealing material (not shown in the figure), thereby forming a display section 620. In an extended region 611 of the glass substrate 610, a large scale integration (hereinafter referred to as “LSI”) chip 630 having a driver function required to drive the display section 620, and a flexible printed circuit (hereinafter referred to as “FPC”) substrate 640 that is connected to an external electronic device are mounted using an ACF for a chip 630a and an ACF for FPC 640a, respectively. When an image signal, a control signal, and a power voltage are given from the outside to the LSI chip 630 through the FPC substrate 640, an image is displayed in the display section 620.

Here, the different types of ACFs, which are the ACF for a chip 630a and the ACF for FPC 640a, are respectively used for the following reasons. It is preferable that the rigid LSI chip 630 be mounted by the rigid ACF for a chip 630a, and that the flexible FPC substrate 640 be mounted by the flexible ACF for FPC 640a. Also, it is preferable to use the ACF 630a that includes small-sized conductive particles for mounting the LSI chip 630 that has narrow pitches, and to use the ACF for FPC 640a that includes relatively large-sized conductive particles for mounting the FPC substrate 640 that has relatively wide spaces between wires.

Particularly, pitches in an LSI chip have been increasingly made narrower in recent years, and the size of the conductive particles in the ACF for a chip 630a is becoming smaller so as to prevent one conductive particle or a plurality of conductive particles in an aggregate from coming in contact with two adjacent terminals simultaneously. However, the size of a conductive path to be formed depends on the size of the conductive particles, and because the conductive path becomes larger as the conductive particle becomes larger, it is preferable that the size of the conductive particle be not small.

In view of this point, Japanese Patent Application Laid-Open Publication No. 2006-237486 discloses a configuration in which a thin insulation coating is formed on surfaces of bumps of an LSI chip. This configuration makes it possible to prevent a plurality of conductive particles in an aggregate from coming in contact with two adjacent terminals simultaneously without making the size of the respective conductive particles too small.

However, in the configuration where conductive particles are used as described above, it is not possible to make the pitches narrower than the diameter of a single conductive particle. Also, the smaller a conductive particle is, the smaller an elasticity of the conductive particle becomes, and therefore, the conductive particles may not be able to absorb variations in height of bumps and the like, which may cause a connection problem.

To solve these problems, Japanese Patent Application Laid-Open Publication No. 2005-266091 discloses a display panel that is provided with protrusions made of a resin and a conductive layer disposed on these protrusions as a configuration for connecting terminals of the display panel to bumps of the LSI chip without using the ACF. According to this configuration, the protrusions made of a resin can be appropriately pressed down, and because the variations in height of the bumps and the like can therefore be absorbed, an excellent connecting condition can be achieved.

### RELATED ART DOCUMENTS

### Patent Documents

Patent Document 1: Japanese Patent Application Laid-Open Publication No. 2006-237486

Patent Document 2: Japanese Patent Application Laid-Open Publication No. 2005-266091

### SUMMARY OF THE INVENTION

### Problems to be Solved by the Invention

However, in the conventional terminal configuration disclosed in the above-mentioned Japanese Patent Application Laid-Open Publication No. 2005-266091, the resin that constitutes the protrusions is likely to be peeled off from the glass substrate at their border. This may cause the terminals to be broken, possibly resulting in a bad connection.

That is, in the above-mentioned conventional example, the size of the protrusions is approximately the size of a single terminal or a plurality of terminals, and areas thereof in contact with the glass substrate are small, which makes them likely to be peeled off. A plurality of protrusions are formed for a single terminal or a plurality of terminals, corresponding to the number of bumps in the LSI chip, and therefore, a large number of borders between the protrusions and the glass substrate are created. The surrounding of the respective terminals that include protrusions is filled with an adhesive agent for bonding the LSI chip to the glass substrate, and by this adhesive agent, a force to remove the protrusions from the glass substrate is generated. This force is concentrated at the borders (outer peripheries) of the protrusions, and as a result of a strong force being concentrated at a large number of the borders, the protrusions may be removed from the glass substrate, causing the terminals to be broken.

An object of the present invention is to provide a device substrate such as a display panel that includes a terminal through which the display device can be connected to an electronic part such as an LSI chip, which is bonded by an adhesive agent, and that can suppress a breakage of the terminal caused by the adhesive agent, and a method for manufacturing such.

### Means for Solving the Problems

A first aspect of the present invention is a device substrate in which an electronic part is mounted on a substrate by a non-conductive adhesive agent, including:

an insulating substrate;

an insulating layer having a plurality of terminals to be connected to the electronic part formed thereon, the insulating layer being provided continuously between all of the plurality of terminals and the substrate, and having a prescribed elasticity; and

an adhesive agent disposed in a prescribed area that includes an area between the insulating layer and the electronic part,

wherein an outer peripheral portion of the insulating layer is disposed outside of the area in which the adhesive agent is disposed.

A second aspect of the present invention is the first aspect of the present invention, further including:

a plurality of wires on the substrate, the plurality of wires being connected to the plurality of terminals,

wherein a plurality of contact holes are formed in the insulating layer to connect the plurality of terminals and the plurality of wires, respectively.

A third aspect of the present invention is the second aspect of the present invention, wherein the plurality of contact holes are formed in the area in which the adhesive agent is formed.

A fourth aspect of the present invention is the second aspect of the present invention,

wherein the plurality of contact holes are respectively formed at positions that are remote from the terminals such that a sag of the plurality of terminals in a direction perpendicular to the substrate plane, which occur in mounting the electronic part, does not cause a connection problem between a corresponding terminal and a corresponding wire.

A fifth aspect of the present invention is the first aspect of the present invention,

wherein the plurality of terminals are made of a material having toughness that can prevent the terminals from being broken due to a sag of the plurality of terminals in the direction perpendicular to the substrate plane, which occurs in mounting the electronic part.

A sixth aspect of the present invention is the fifth aspect of the present invention,

wherein the plurality of terminals are made of a material containing aluminum or an aluminum alloy.

A seventh aspect of the present invention is the first aspect of the present invention,

wherein the plurality of terminals are respectively narrower than a plurality of electrodes, respectively, which are formed in the electronic part so as to be connected to the terminals, in an arrangement direction of the plurality of electrodes, and are respectively longer than the plurality of electrodes in a direction perpendicular to the arrangement direction.

An eighth aspect of the present invention is the seventh aspect of the present invention,

wherein a width of the respective plurality of terminals in the arrangement direction is smaller than half a width of the respective plurality of electrodes in the arrangement direction.

A ninth aspect of the present invention is the first aspect of the present invention,

wherein the adhesive agent is a non-conductive film or a non-conductive paste.

A tenth aspect of the present invention is the first aspect of the present invention,

wherein the adhesive agent contains a conductive particle, and

wherein the conductive particle has a hardness that is sufficient enough to break through a high resistance film, which may be formed on the plurality of terminals, by a pressure applied in mounting the electronic part.

An eleventh aspect of the present invention is the tenth aspect of the present invention,

wherein the conductive particle is made of a single material having the above-mentioned hardness.

A twelfth aspect of the present invention is the tenth aspect of the present invention,

wherein the conductive particle has a particle size of 1 micrometer or smaller.

A thirteenth aspect of the present invention is the first aspect of the present invention,

wherein the insulating layer has a portion that protrudes in a direction perpendicular to a plane of the substrate in each of areas that include one or two or more adjacent terminals among the plurality of terminals.

A fourteenth aspect of the present invention is the thirteenth aspect of the present invention,

wherein the insulating layer is formed so as to protrude in the direction perpendicular to the plane of the substrate in each of the terminals.

A fifteenth aspect of the present invention is the thirteenth aspect of the present invention,

wherein the insulating layer has a plurality of protrusions that protrude in the direction perpendicular to the plane of the substrate on a surface that makes contact with the plurality of terminals.

A sixteenth aspect of the present invention is the first aspect of the present invention,

wherein the electronic part includes a plurality of electrodes to be connected to the plurality of terminals, and

wherein the insulating layer is made of a material having a low resilience so that stress is concentrated on portions of the plurality of terminals, which are to be in contact with edge sections of the plurality in mounting the electronic part.

A seventeenth aspect of the present invention is the first aspect of the present invention,

wherein the electronic part includes a plurality of electrodes to be connected to the plurality of terminals, and

wherein, of the plurality of electrodes that constitute respective groups of electrodes, at least a plurality of electrodes constituting one group are respectively connected to one corresponding terminal along an extending direction of the terminal.

An eighteenth aspect of the present invention is the first aspect of the present invention,

wherein the electronic part includes a plurality of electrodes to be connected to the plurality of terminals, and

wherein prescribed recesses or protrusions are respectively formed on respective faces of the plurality of electrodes to be in contact with the plurality of terminals so as to break through a high resistance film that may be formed on the plurality of terminals.

A nineteenth aspect of the present invention is the eighteenth aspect of the present invention,

wherein the electronic part is an integrated circuit module, and includes a plurality of bump electrodes, which correspond to the plurality of electrodes, and

wherein, in order to form, on the respective faces of the plurality of bump electrodes, protrusions having a height that is sufficient to break through the high resistance film that may be formed on the plurality of terminals, a thickness of a passivation layer formed on a surface facing the above-mentioned faces is made substantially the same as the above-mentioned height.

A twentieth aspect of the present invention is the first aspect of the present invention,

wherein the electronic part includes a plurality of electrodes to be connected to the plurality of terminals, and

wherein the respective plurality of terminals includes, near at least one of portions to be in contact with an edge section of respective one of the plurality of electrodes that are connected in mounting the electronic part, portions that are narrower in a direction parallel to an extending direction of that portion.

A twenty-first aspect of the present invention is the twentieth aspect of the present invention,

wherein the respective plurality of terminals have slits formed in the above-mentioned portions that are narrower.

A twenty-second aspect of the present invention is the twentieth aspect of the present invention,

wherein a plurality of wires respectively connected to the plurality of terminals are formed on the substrate, and

wherein each of the plurality of terminals has the portion that is made narrower near at least one of portions to be in contact with the edge sections, except at a portion closest to a corresponding wires of the plurality of wires.

A twenty-third aspect of the present invention is the twenty-second aspect of the present invention,

wherein each of the plurality of terminals has the portion that is narrower formed near a portion closest to an end of the terminal among portions to be in contact with the edge sections.

A twenty-fourth aspect of the present invention is the first aspect of the present invention,

wherein the substrate includes a display section that displays an image, and wherein the electronic part includes a driver element that drives the display section in accordance with a signal given from an outside.

A twenty-fifth aspect of the present invention is the twenty-fourth aspect of the present invention,

wherein the display section includes:

a light reflective unit that reflects light incident from the outside; and

a liquid crystal layer that controls transmittance of light incident from the outside and light reflected by the reflective unit, and

wherein the light reflective unit is formed of the same material as a material of the terminals.

A twenty-sixth aspect of the present invention is the first aspect of the present invention,

wherein the electronic part includes an integrated circuit chip and a flexible substrate, and

wherein a same kind of the adhesive agent is formed between the insulating layer and the integrated circuit chip, and between the insulating layer and the flexible substrate.

A twenty-seventh aspect of the present invention is a method for manufacturing a device substrate in which an electronic part is mounted on a substrate by a non-conductive adhesive agent, including:

an insulating layer formation step of forming an insulating layer having a prescribed elasticity on an insulating substrate;

a terminal formation step of forming a plurality of terminals to be connected to the electronic part on the insulating layer;

a bonding preparatory step of forming an adhesive agent in a prescribed area that includes an area between the insulating layer and the electronic part; and

a mounting step of mounting the electronic part by pressure-bonding the electronic part to the substrate using a prescribed pressure-bonding method,

wherein, in the insulating layer formation step, the insulating layer is continuously provided between all of the plurality of terminals and the substrate, and an outer peripheral portion of the insulating layer is formed outside of the area in which the adhesive agent is formed.

A twenty-eighth aspect of the present invention is the twenty-sixth aspect of the present invention, further including:

a pattern formation step of forming a conductive pattern that becomes a plurality of wires to be respectively connected to the plurality of terminals on the substrate; and

a contact hole formation step of forming contact holes for connecting the plurality of terminals to the plurality of wires in the insulating layer.

A twenty-ninth aspect of the present invention is the twenty-seventh aspect of the present invention, further including:

a display section formation step of forming, on the substrate, a display section that displays an image,

wherein, in the terminal formation step, the terminals are formed by using the same method as a film formation method that is to be used when a light reflective unit for reflecting incident light from the outside is formed in the display unit, and by using the same material as a material to be used for the light reflective unit.

### Effects of the Invention

According to the first aspect of the present invention, an insulating layer having a prescribed elasticity is continuously formed between all of a plurality of terminals and a substrate, and the outer periphery of the insulating layer is positioned outside of an area in which an adhesive agent is formed, and therefore, the outer periphery (boundary section) of the insulating layer does not overlap the area in which the adhesive agent is formed. This makes it possible to prevent the insulating film from being peeled off at the border by the adhesive agent, and consequently, prevent a breakage of the terminals. The insulating layer is formed directly below the terminals, and therefore, with the elasticity of the insulating layer, the terminals are constantly pressure-bonded to the terminals of the electronic part, and a stable electrical connection therebetween is ensured.

According to the second aspect of the present invention, it is possible to use a commonly-adopted manufacturing process for a device substrate such as a display panel, i.e., forming a wiring pattern on a glass substrate, and thereafter forming an insulating layer such as an interlayer insulating film or a passivation layer thereon. This allows for a lower manufacturing cost.

According to the third aspect of the present invention, the contact hole is covered by the adhesive agent, and therefore, it is possible to protect the contact hole. Also, because the terminal is not exposed at the position where the contact hole is formed, a corrosion of the terminal can be prevented.

According to the fourth aspect of the present invention, the contact holes are formed at positions that are far enough from the terminals, respectively, so that a sag of the terminals in a perpendicular direction, which occurs in mounting the electronic part, does not cause a connection problem between corresponding terminals and corresponding wires. This prevents the sagged portion of the terminal around the contact hole from having a crack and being ruptured, for example, and the stable electrical connection can therefore be maintained.

According to the fifth aspect of the present invention, the terminals are made of a material having a toughness that can prevent a breakage caused by the sag, and therefore, even when the terminals are warped, cracks are not likely to be formed or not formed at all (in a portion bended significantly) and an stable electrical connection can be obtained.

According to the sixth aspect of the present invention, the terminals are formed of a material containing aluminum or an aluminum alloy, which allows the terminals to be formed of a material that is inexpensive, and has a high toughness.

According to the seventh aspect of the present invention, the terminals are respectively narrower than the plurality of electrodes formed in the electronic part in the arrangement direction of the electrodes. This allows the terminals to be pressed down evenly by the electrode (by the contact surface thereof), which prevents the terminals from being tilted and off-balanced, and as a result, deterioration of the electrical connection can be prevented. The terminals are longer than the electrodes in a direction perpendicular to the arranging direction, and therefore, even when the position of the electronic part is offset in the perpendicular direction, a stable electrical connection can be maintained in the electrodes.

According to the eighth aspect of the present invention, the width of the terminals in the arrangement direction is smaller than a half of the width of the electrodes in the arrangement direction, and therefore, even if the position of the electrodes are offset to the left or to the right from an ideal central position by a quarter of the width of the electrodes, for example, the terminals can be pressed by the electrodes evenly. As a result, the terminals do not tilt, and the stable electrical connection can be maintained.

According to the ninth aspect of the present invention, because the adhesive agent is a non-conductive film or a non-conductive paste, conductive particles are not necessary for connection. This allows for an easy and inexpensive bonding of the electronic part.

According to the tenth aspect of the present invention, the conductive particles contained in the adhesive agent have a hardness that can break through a high resistance film, which may be formed on the terminal, by a pressure applied in mounting the electronic part. This makes it possible to remove the high resistance film easily, and to thereby secure the electrical connection.

According to the eleventh aspect of the present invention, the conductive particles are made of a single material, which makes it easier to achieve a sufficient hardness. The conductive particles not having a layered structure, which are typically made of a metal (such as nickel) alone, can be easily manufactured at a low cost.

According to the twelfth aspect of the present invention, the particle size of the conductive particle is 1 micrometer or smaller, which makes it easier to break through the high resistance film. Because it is difficult to form a layered structure for the conductive particle of such a small size, it is preferable that the conductive particle be made of a single (metal) material as in the eleventh aspect of the present invention.

According to the thirteenth aspect of the present invention, the insulating layer includes a portion that protrudes in a direction perpendicular to the substrate plane in every area including one terminal or every area including two or more adjacent terminals among a plurality of terminals, and therefore, the terminals are sufficiently pressed to the electrodes of the electronic part, and the electrical connection can be secured.

According to the fourteenth aspect of the present invention, each of the terminals can be pressed sufficiently to the electrodes of the electronic part, thereby securing the electrical connection.

According to the fifteenth aspect of the present invention, typically a large number of protrusions that protrude in the direction perpendicular to the substrate plane are formed on the insulating layer. The tip portions of the protrusions can break through the high resistance film that may be formed on the terminals, and therefore, it becomes possible to remove the high resistance film with ease, which can secure the electrical connection.

According to the sixteenth aspect of the present invention, the insulating layer is made of a material with a low resilience, and therefore, stress is concentrated on respective portions of a plurality of terminals, which make contact with the edge sections of the electrode in mounting the electronic part, and the above-mentioned portions are significantly stretched, thereby undergoing a high tensile stress. As a result, the high resistance film that may be formed on the above-mentioned portion is ruptured. Thus, the high resistance film can be easily removed and the electrical connection can be secured.

According to the seventeenth aspect of the present invention, a plurality of electrodes constituting one group are respectively connected to one corresponding terminal along an extending direction of the terminal, and therefore, the number of edge sections of the electrodes that make contact with one terminal is increased. Because the high resistance film, which may be formed on the terminals, is ruptured at the borders, when the number of edges portions is increased, the number of places where the high resistance film is ruptured is also increased. This makes it possible to remove the high resistance film at a greater scale, which secures the electrical connection more reliably.

According to the eighteenth aspect of the present invention, prescribed recesses or protrusions are formed on a surface of the electrodes, and therefore, many places of the high resistance film, which may be formed on the terminals sections, can be broken through at the edge sections of the electrodes. Accordingly, it is possible to remove many of the high resistance films, which secures the electrical connection more reliably.

According to the nineteenth aspect of the present invention, the thickness of the passivation layer is made substantially the same as the height of the protrusions, and therefore, it becomes possible to easily remove the high resistance film by the protrusions and to secure the electrical connection.

According to the twentieth aspect of the present invention, the terminal includes, near at least one portion among (one or more) portions that make contact with edge sections of the electrode, a portion having has a length thereof in the direction parallel to the extending direction of the above-mentioned portion made smaller. Because this portion becomes structurally weak, when this portion makes contact with the edge section of the electrode in mounting the electronic part, a crack is created, for example. As a result, the high resistance film that may be formed in the portion is ruptured, and therefore, it becomes possible to easily remove the high resistance film and to secure the electrical connection.

According to the twenty-first aspect of the present invention, slits are formed so that the length of the portion with the smaller length can be easily reduced.

According to the twenty-second aspect of the present invention, the width of the portion that is near the portion that makes contact with the edge section and that is closest to the corresponding wire is not made smaller. This makes it possible to prevent an occurrence of a problem of cutting off or reducing a current that flows to the wire, which is caused by such a portion being ruptured, for example.

According to the twenty-third aspect of the present invention, among the portions that make contact with the edge sections, the width of the portion near the portion closest to the end of the terminal is made narrower, and therefore, even when the portion is ruptured, for example, a current that flows to the wire is not affected at all, and it is possible to reliably prevent an occurrence of a problem of cutting off or reducing the current.

According to the twenty-fourth aspect of the present invention, it becomes possible to provide a display panel having a display section, such as a liquid crystal panel, with the effects similar to those of the first aspect of the present invention.

According to the twenty-fifth aspect of the present invention, the terminals are formed in a step of forming a reflective electrode in (a pixel formation unit of) the display unit. This allows the device substrate, which is a display panel having such terminals, to be manufactured through a conventional manufacturing process of a liquid crystal display device. This eliminates a need of developing and introducing a new manufacturing process, thereby achieving a low cost manufacturing.

According to the twenty-sixth aspect of the present invention, the same kind of adhesive agent can be used, and because there is no need to take into account an installation accuracy, the integrated circuit chip and the flexible substrate can be formed closely to each other. This makes it possible make the frame area of the device substrate narrower. Also, because only one kind of adhesive agent is used, the manufacturing process can be simplified.

According to the twenty-seventh aspect of the present invention, it is possible to provide a method for manufacturing a device substrate that can achieve effects similar to those of the first aspect of the present invention.

According to the twenty-eighth aspect of the present invention, it is possible to provide a method for manufacturing a device substrate that can achieve effects similar to those of the second aspect of the present invention.

According to the twenty-ninth aspect of the present invention, in the step of forming the terminals, the terminals are formed by using the same process as a film formation process that is used when a reflective unit is formed, and by using the same material as the material to be used for the light reflective unit, and therefore, even when a light reflective unit is not formed in the step of forming the display section, the terminals can be easily formed at a low cost using the manufacturing device and the film forming method used to form the light reflective unit, which eliminates a need of an additional step.

### BRIEF DESCRIPTION OF THE DRAWINGS

FIG. 1 is a schematic plan view showing a liquid crystal panel according to an embodiment of the present invention.

FIG. 2 is a perspective view showing the configuration of a liquid crystal panel 10 shown in FIG. 1 according to the embodiment.

FIG. 3 is a cross-sectional view of the liquid crystal panel 10 taken along the line indicated with arrows A-A in FIG. 2 according to the embodiment.

FIG. 4 is a cross-sectional view showing a configuration of an area near a terminal of the cross-sectional view shown in FIG. 3 according to the embodiment.

FIG. 5 is a cross-sectional view showing a display wire and an insulating layer so as to illustrate in a simple manner a manufacturing step of a glass substrate including a terminal connected to a bump electrode of an LSI chip according to the embodiment.

FIG. 6 is a cross-sectional view showing a contact hole that is formed in the insulating layer according to the embodiment.

FIG. 7 is a cross-sectional view showing a terminal formed on the insulating layer according to the embodiment.

FIG. 8 is a plan view of an LSI chip 40 and its surrounding area as viewed from a rear surface side of a glass substrate 20 according to the embodiment.

FIG. 9 is a cross-sectional view showing an example of positions of a bump electrode and a terminal relative to each other when they are connected as viewed from a direction perpendicular to a direction in which a terminal 24 is extended according to the embodiment.

FIG. 10 is a cross-sectional view showing another example of positions of a bump electrode and a terminal relative to each other when they are connected as viewed from a direction perpendicular to the direction in which the terminal 24 is extended according to the embodiment.

FIG. 11 is a plan view showing the connection relation between two bump electrodes and one terminal in a modification example of the embodiment.

FIG. 12 is a cross-sectional view showing the configuration of the two bump electrodes and the one terminal shown in FIG. 11 in a modification example of the embodiment.

FIG. 13 is a cross-sectional view showing a configuration of an area near the bump electrode having protrusions at edges thereof and a terminal before the bump electrode is connected to the terminal in a modification example of the embodiment.

FIG. 14 is a cross-sectional view showing a configuration of an area near the bump electrode having the protrusions at edges thereof and the terminal after the bump electrode is connected to the terminal in a modification example of the embodiment.

FIG. 15 is a plan view showing an example of a shape of a terminal in a modification example of the embodiment.

FIG. 16 is a cross-sectional view of the electrode and the terminal shown in FIG. 15 in the modification example of the embodiment.

FIG. 17 is a plan view showing another example of a shape of the terminal in a modification example of the embodiment.

FIG. 18 is a plan view showing yet another example of a shape of the terminal in a modification example of the embodiment.

FIG. 19 is a plan view showing an example of a shape of the terminal that is wider than the bump electrode in a modification example of the embodiment.

FIG. 20 is a plan view showing another example of a shape of the terminal that is wider than the bump electrode in a modification example of the embodiment.

FIG. 21 is a schematic plan view of a conventional liquid crystal panel.

### DETAILED DESCRIPTION OF EMBODIMENTS

### 1. Configuration of Liquid Crystal Panel

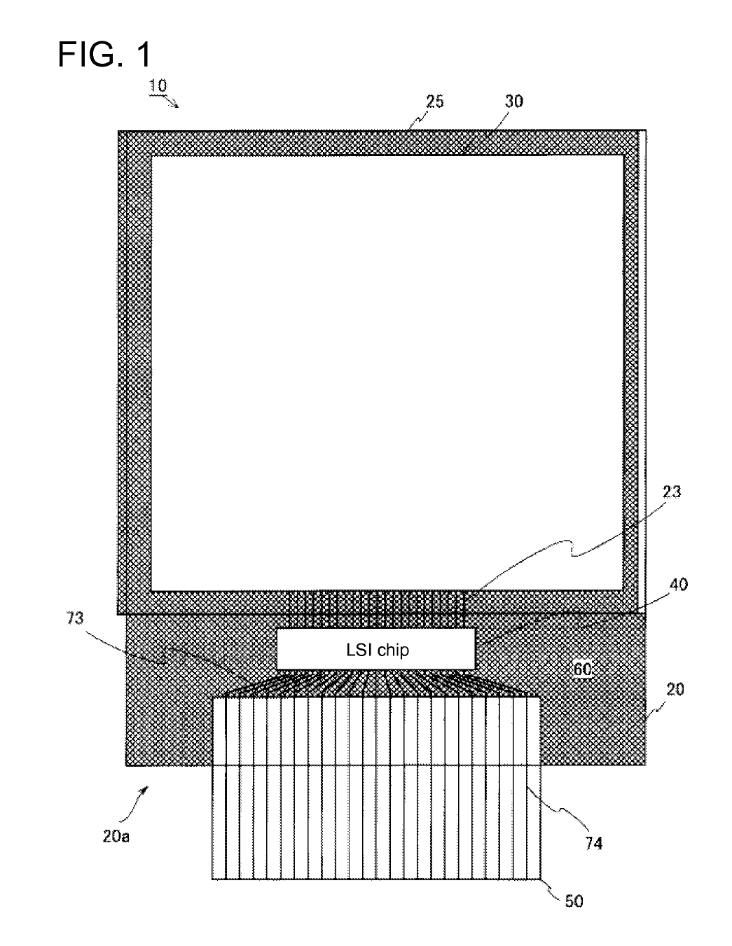

FIG. 1 is a schematic plan view showing the configuration of a liquid crystal panel 10 according to an embodiment of the present invention. As shown in the figure, the liquid crystal panel 10 is provided with two glass substrates 20 and 25 disposed facing each other and an LSI chip 40. Electronic parts such as a capacitor may also be provided.

A display section 30 in which liquid crystal (not shown in the figure) is sealed by a sealing material (not shown in the figure) is formed in a space sandwiched between the two glass substrates 20 and 25. In an extended region 20a of the glass substrate 20, the LSI chip 40 having the driver function required to drive the liquid crystal, and an FPC substrate 50 connected to the outside are mounted.

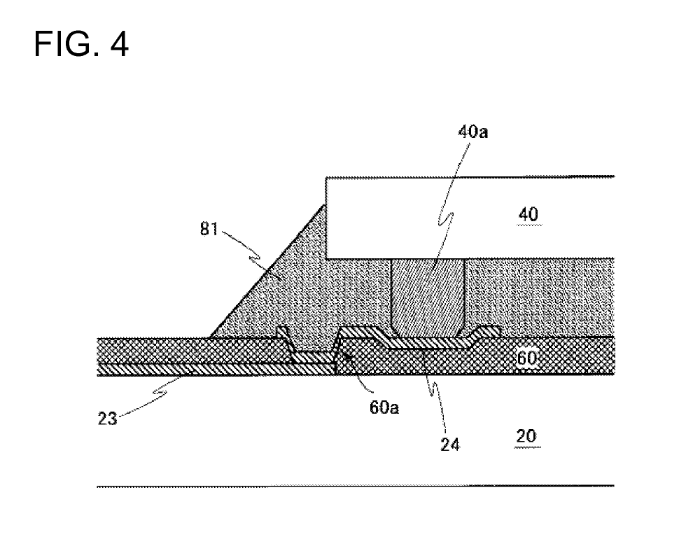

On the areas other than the display section 30 of the glass substrate 20, an insulating layer 60 having an elasticity that is suitable for mounting the LSI chip 40 is formed, and on this insulating layer 60, the LSI chip 40 and the FPC substrate 50 are mounted (through wires connected to the terminals shown in FIG. 4, which will be described later). In this liquid crystal panel, when an image signal is given from the outside to the LSI chip 40 through the FPC substrate 50, the LSI chip 40 displays an image in the display section 30.

The LSI chip 40 is a bare chip (chip before packaging) in which a circuit pattern of a gate driver, a source driver, and a DC to DC converter and the like are formed on a surface of a silicon substrate using a microfabrication technique. The LSI chip 40 also has bump electrodes as the connecting terminals for connecting the circuit pattern to the outside. A height of the bump electrodes is approximately 15 μm, for example. The configuration where such an LSI chip 40, which is a bare chip, is bonded with its face down onto the extended region 20a is merely an example, and an LSI device that is obtained by packaging the LSI chip 40 in a surface mount package may also be mounted on the glass substrate 20 (through terminals shown in FIG. 4, which will be described later), for example.

The FPC substrate 50 is made of a 12 to 50 μm-thick flexible insulating film, and on one surface of the insulating film, a plurality of wiring layers are formed of copper foil with the thickness of 8 to 50 μm. The FPC substrate 50 is capable of being bent freely. The wiring layers may be formed not only on one surface of the insulating film, but also on both of the surfaces.

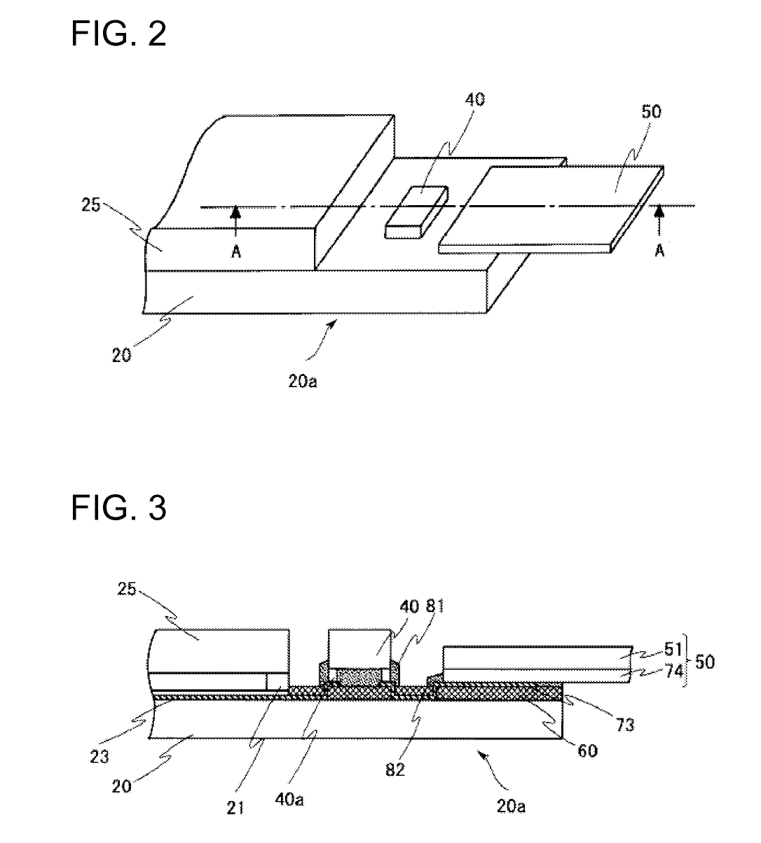

FIG. 2 is a perspective view showing a configuration of the liquid crystal panel 10 shown in FIG. 1, and FIG. 3 is a cross-sectional view of the liquid crystal panel 10 taken along the line indicated with arrows A-A in FIG. 2.

As shown in FIG. 3, the LSI chip 40 is bonded by the face-down bonding using an adhesive agent 81 that does not contain conductive particles (typically a non-conductive film (hereinafter referred to as “NCF”)), and bump electrodes 40a that are formed on a surface of the LSI chip 40 are connected to an end of the FPC wire 73 formed on the extended region 20a and to a display wire 23 extending to the display section 30. Wiring layers 74 formed on an insulating film 51 of the FPC substrate 50 are connected to the other end of the FPC wire 73 through an NCF 82, which is an adhesive agent that does not contain conductive particles. The FPC wire 73 and the display wire 23 are formed simultaneously with other wires in the display section 30, and therefore, the FPC wire 73 and the display wire 23 are formed of a material containing aluminum (Al) or tantalum (Ta).

As described above, the wiring layers 74 of the FPC substrate 50 are connected to input terminals of the LSI chip 40 through the FPC wire 73, and therefore, signals such as an image signal and a clock signal, a reference voltage and the like that are sent from the outside to the respective wiring layers 74 of the FPC substrate 50 are respectively sent to corresponding input terminals of the LSI chip 40.

Also, the respective pixel formation units in the display section 30 are connected to the output terminals of the LSI chip 40 through the display wire 23, and therefore, an image signal outputted from the LSI chip 40 is sent to the respective pixel formation units in the display section 30.

The NCFs 81 and 82 used for such connections are a film-shaped thermo-curable resin such as an epoxy-type resin. The above-described ACF is obtained by mixing microscopic conductive particles into such a resin and by forming the resin into a film. The NCFs 81 and 82 are the same as the ACF, except that the conductive particles are not included. In place of the NCFs 81 and 82, a non-conductive paste that is a thermo-curable resin in a paste form, instead of the film form, and that does not have the conductive particles mixed therein may be used. In the present specification, these non-conductive film and non-conductive paste are collectively referred to as a non-conductive adhesive agent or simply as an adhesive agent. The adhesive agent used below is not limited to an NCF or an NCP, and a wide variety of known adhesive agents that are suitable for bonding an electronic part to an insulating substrate can be used.

Generally, it is not possible to obtain stable electrical connections between the LSI chip 40 and the display wire 23 and between the LSI chip 40 and the FPC wire 73, respectively, by the NCFs 81 and 82 alone without using other constituent elements. The bump electrodes 40a of the LSI chip 40 and terminals (shown in FIG. 4) connected to the bump electrodes 40a are generally made of a hard metal. For this reason, the bump electrodes and the terminals are not elastically deformed almost at all, and a stable electrical connection between the two cannot be ensured by the adhesive agents alone. Particularly, if the adhesive agents are expanded by absorbing moisture, the connection between the two is easily cut off. Moreover, if there is variation in height of the bump electrodes 40a, some of the bump electrodes 40a and the terminals 24 may not be electrically connected sufficiently or not connected at all.

In view of this point, an insulating layer 60, which has an elasticity suitable for maintaining a constant connection (pressure-bonding) between the two even in above-mentioned circumstances, is provided. The insulating layer 60 is disposed below at least the bump electrodes 40a (and corresponding terminals connected to the display wire 23 and to the FPC wire 73, respectively). This way, with the above-mentioned elasticity of this insulating layer 60, connections between the wires and the bump electrodes 40a obtained by pressure-bonding can be maintained, thereby ensuring stable electrical connections between the respective members.

Such a function by the elasticity of the insulating layer 60 can be achieved as long as the insulating layer 60 is disposed in areas below the bump electrodes 40a. However, because the LSI chip 40 has a large number of bump electrodes 40a arranged with narrow pitches, forming the insulating layer 60 only in areas below the bump electrodes 40a makes the manufacturing process complex, and is therefore not preferable. Although a configuration where a plurality of bump electrodes 40a are placed together and the insulating layer 60 is formed below them can be employed, it is preferable to form the insulating layer 60 over the entire surface (areas other than the area where the display section 30 is formed) of the glass substrate 20 because it allows for a simple manufacturing process as described later.

Further, as described above, the adhesive agents for fixing the LSI chip to the glass substrate are formed around the terminals, thereby generating a force to remove the terminals from the glass substrate. This force is concentrated at the border (the outer periphery) of the insulating layer in the above-mentioned conventional configuration, which may cause the insulating layer to peel off from the glass substrate at this border, and as a result, the terminals may be broken. Thus, it is preferable that the border (outer periphery) portions of the insulating layer 60 at least do not make contact with the adhesive agents. Further, even if the border is not in contact with the adhesive agent, considering that the insulating layer 60 is generally made of a material that is not firmly attached to the glass substrate 20a, it is preferable the insulating layer 60 make contact with the glass substrate 20 in a sufficiently large area.

Also, besides such disadvantages caused by the configuration that the border (outer periphery) portion of the insulating layer is in contact with the adhesive agents, if a insulating layer surrounded by the border is formed so as to protrude from the glass substrate in the height direction as in some conventional configuration, the border portion is subject to greater stress, which makes the insulating layer more likely to be peeled off. Thus, the insulating layer is preferably formed as a flat layer extended along a surface of the glass substrate 20.

If the insulating layer is to be formed in a protruding shape, a material that is capable of maintaining such a shape needs to be used, and therefore, a material that is not solid enough to maintain such a shape (a material that spreads out) cannot be used, which limits the materials that can be used. Also, forming such a protruding shape requires not only an additional manufacturing step, but also difficult work such as designing a suitable shape for generating an appropriate elasticity and forming the shape accurately with no variations.

In contrast, when the insulating layer is formed flat as in this embodiment, it becomes possible to check the connecting condition after the LSI chip 40 is mounted, by inspecting indentations in the terminals 24, which are made by the bump electrodes 40a upon pressure-bonding, from the rear surface of the substrate using a differential microscope. Such an indentation check with a differential microscope has been widely performed, but when the insulating layer is formed so as to protrude in the terminals, the variations in the thickness thereof in a direction perpendicular to the substrate plane becomes so large that the connecting condition cannot be verified through the differential microscope, which is designed for inspecting indentations formed on a flat surface. This creates a need for a new scheme for verifying the connecting condition, and as a result, the inspection cost is increased. In view of the above-mentioned points, it is understood that the configuration of this embodiment that the insulating layer is formed on the glass substrate 20 in a layer form is highly preferable.

In the configuration of this embodiment in which the border (outer periphery) of the insulating layer is not in contact with the adhesive agents (because the border overlap the outer periphery of the glass substrate 20), even when the peripheries of the terminals are formed so as to protrude, it does not make the insulating layer more likely to be peeled off. It is certainly more preferable that the insulating layer 60 be formed to have the uniformly same height, but because there is only a small risk of the insulating layer 60 being broken at boundary between areas of different heights and thereby being peeled off, and because the border (outer periphery) of the insulating layer with the glass substrate where the peeling is likely to start is not in contact with the adhesive agents, the insulating layer 60 may be formed so as to protrude at the peripheries of one or more of the successive terminals or at the periphery of each terminal.

Next, the detailed structure of an area near the above-mentioned terminal, which is to be connected to the bump electrode 40a, is described with reference to FIG. 4. Below, the explanation is mainly made for the connection between the bump electrodes 40a of the LSI chip 40 and the respective terminals, but the wiring layers 74 that are formed on the insulating film 51 of the FPC substrate 50 and the respective terminals connected to the FPC wire 73 formed in the extended region 20a are connected in the same manner, and therefore, the explanation thereof is omitted.

### 2. Connection Structure of Bump Electrode and Terminal

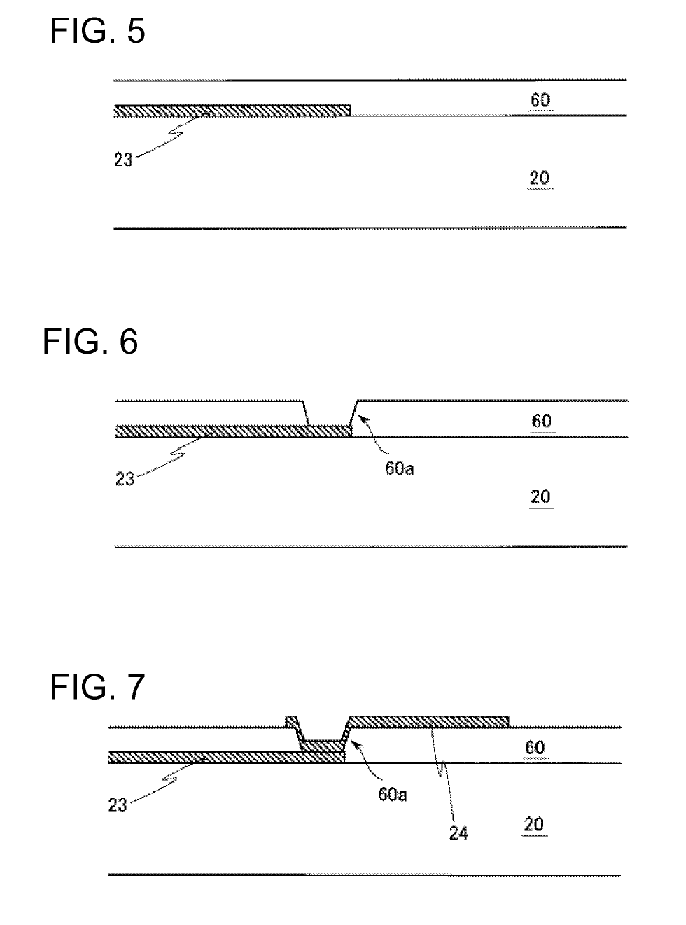

FIG. 4 is a cross-sectional view showing the configuration of an area near the terminal shown in the cross-sectional view in FIG. 3. As shown in this FIG. 4, the terminal 24 connected to the bump electrode 40a of the LSI chip 40 is formed on the insulating layer 60, and is connected to the display wire 23, which is formed below the insulating layer 60, through a contact hole 60a formed in the insulating layer 60. That is, the terminal 24 refers to the entire metal electrode that includes a portion connected to the bump electrode 40a and that extends to the contact hole 60a. The NCF 81, which is an adhesive agent, is formed so as to cover the terminal 24 formed on a surface below the LSI chip 40 and the contact hole 60a formed near the surface. A manufacturing process of the glass substrate 20 having such a configuration is described with reference to FIGS. 5 to 7.

FIG. 5 is a cross-sectional view showing a display wire and an insulating layer so as to illustrate in a simple manner a manufacturing step of a glass substrate having a terminal connected to a bump electrode of the LSI chip. FIG. 6 is a cross-sectional view showing a contact hole formed in the above-mentioned insulating layer. FIG. 7 is a cross-sectional view showing a terminal formed on the insulating layer.

As shown in FIG. 5, the display wire 23 is formed on the glass substrate 20. Specifically, a multilayer film made of a plurality of metal films, for example, is first formed on a surface of the glass substrate 20 by sputtering. In place of a glass substrate, an insulating substrate made of a transparent insulating material such as quartz or plastic may be used. The wire may be a single layer of multiple layers of chrome (Cr), molybdenum (Mo), tantalum (Ta), tungsten (W), copper (Cu), indium tin oxide (ITO), indium zinc oxide (IZO), or the like, or an alloy made of these materials and a minute amount of impurities.

Next, a resist is applied onto the multilayer film, and exposure and development are performed to form a resist pattern that becomes a mask to be used when the display wire 23 (and the FPC wire 73) is etched. Using the formed resist pattern as a mask, dry-etching is performed in order of Ti, Al, and Ti, and then the resist pattern is stripped. As a result, the display wire 23 (and the FPC wire 73) is formed on the glass substrate 20. The preceding manufacturing steps are known, and therefore, the detailed description is omitted.

Next, the insulating layer 60, which is an insulating film made of organic resin, for example, is formed in the film thickness of approximately 3 to 4 μm, for example. It is preferable that the composition and the film thickness of the above-mentioned organic resin be set such that the surface of the resultant film becomes substantially flat. Specifically, the insulating layer 60 can be formed by a known method, such as a method of forming the insulating layer by transferring an organic resin formed on a base film made of PET (polyethylene terephthalate) in a layer-shape to a substrate and by thereafter removing the base film, or a method of forming the insulating layer by spraying an organic resin from a nozzle and by coating a substrate with the organic resin through a spin-coating method, for example.

The above-mentioned organic resin is made of a photosensitive material. After the organic resin is applied and formed so as to become a prescribed film thickness, exposure and development are performed using a photomask, and as a result, the contact hole 60a shown in FIG. 6 is formed at a prescribed position of the insulating layer 60. The insulating layer 60 does not need to be made of a photosensitive material, and the contact hole 60a may be formed by performing a known etching treatment that does not use photolithography or the like, for example.

It is preferable that the contact hole 60a be formed so as to have some distance from the position where the terminal 24 makes contact with the bump electrode 40a. In other words, when the terminal 24 is connected to the bump electrode 40a by the NCF 81, they are strongly bonded to each other by pressure, and therefore, the terminal 24 is warped toward the side of the insulating layer 60. Therefore, if the contact hole 60a were formed at a position close enough to be affected by this sag, a portion of the terminal 24 on a surface of the contact hole 60a would be also warped, and as a result, the electrical connection between the terminal 24 and the display wire 23 may be deteriorated or be cut off in the contact hole 60a. The sagged portion of the terminal 24 around the contact hole 60a may be cracked and thereby ruptured, for example. Therefore, it is preferable that the position of the contact hole 60a be far enough from the position where the terminal 24 makes contact with the bump electrode 40a so that the electrical connection is not deteriorated or cut off due to the sag (that is, a displacement in a direction perpendicular to the substrate plane) caused by the contact between the terminal and the bump electrode.

Further, it is preferable that the position of the contact hole 60a be close enough to the position where the terminal 24 makes contact with the bump electrode 40a so that the contact hole 60a can be covered by the NCF 81. The NCF 81 is formed on the bottom surface of the LSI chip 40 so as to bond the LSI chip 40 to the substrate surface, but it is common that the NCF 81 is also formed in the periphery of the bottom surface including a lower area of the side surfaces of the LSI chip 40 for a stable bonding. Therefore, when the contact hole 60a is formed within an area where the NCF 81 is formed, it becomes possible to protect the contact hole 60a and to prevent a corrosion of the terminal 24 because the terminal 24 is not exposed in the contact hole 60a. With such a structure, a metal that is likely to corrode such as aluminum can be readily used for the terminal 24 without taking any preventive measures against corrosion.

After the insulating layer 60 is exposed and developed so as to form the contact hole 60a at an appropriate position as described above, the terminal 24 shown in FIG. 7 is formed of aluminum (Al), indium tin oxide (ITO), or indium zinc oxide (IZO) or the like, for example, at a prescribed position by sputtering or the like. Known conductive materials can be appropriately used for this terminal 24.

In this embodiment, this terminal 24 is formed in a step of forming a reflective electrode that is typically formed in (a pixel formation unit of) a reflective or transflective liquid crystal display device. In this case, the terminal 24 is made of a material with a high reflectance such as Al, Ag, or an alloy made of such materials and a minute amount of impurities, for example. Although a reflective electrode is not formed in a transmissive liquid crystal display device, even in such a case, it is preferable that the terminal 24 be formed by using a manufacturing device and a manufacturing process used for forming the reflective electrode. When the terminal 24 is formed in the step of forming the reflective electrode as described above, it is possible to manufacture the liquid crystal display device of the present invention using a conventional process of manufacturing a liquid crystal display device without developing or introducing a new manufacturing process, which makes possible a low cost manufacturing.

It is preferable that the terminal 24 be made of a conductive material with a high toughness such as Al, for example, rather than a material with a low toughness such as ITO. This is because, by using a material with a high toughness, even when the terminal 24 makes contact with the bump electrode 40a and is sagged, cracks are not likely to occur, or do not occur at all (in a portion that sagged significantly), and a stable electrical connection can be obtained. The configuration of this terminal 24 is further described in detail with reference to FIGS. 8 to 10.

FIG. 8 is a plan view of the LSI chip 40 and its surrounding area as viewed from a rear surface side of the glass substrate 20. The number of the display wires 23 and the FPC wires 73, and the number of the bump electrodes 40a corresponding to those wires are often more than dozens or hundreds in an actual device, but they are simplified in the figure. The width of the wires and the distances between the wires are also simplified, and do not reflect actual widths or distances.

Although not shown in FIG. 8, the NCF 81 is formed on and around (the bottom surface of) the LSI chip 40, and by this NCF 81, the LSI chip 40 is bonded to the glass substrate 20 by thermo-compression bonding. A description of such a thermo-compression bonding process is known and therefore omitted.

Each of the bump electrodes 40a (its cross-section parallel to the substrate plane) is illustrated as a circular shape, but the shape is not limited to such. It is preferable that the bump electrode 40a be formed such that, when compared with a length of a cross-sectional portion of the terminal 24 (along the direction towards the display wire 23 and to the FPC wire 73), which is parallel to the substrate plane, the cross-sectional portion becomes significantly shorter in a direction in which the terminals 24 are extended, and becomes wider in a direction perpendicular to the extending direction (in other words, the bump electrode 40a slightly sticks out from the terminal 24 in the horizontal direction of the figure).

This way, even if the LSI chip 40 and the glass substrate 20 are misaligned to some extent in a direction along the shorter side of the LSI chip 40 upon mounting (through a chip dispenser or the like), a stable electrical connection can be established. In other words, as shown in FIG. 8, even if the bump electrodes 40a are slightly misaligned in the direction along the shorter side of the LSI chip 40, as long as the positions are not misaligned in a direction perpendicular to that direction, the bump electrodes 40a are located on the terminals 24, and therefore, the electrical connection is not affected by the misalignment. The length of this terminals 24 in the direction along the shorter side can be made significantly longer (that is, longer than a distance between two adjacent bump electrodes 40a, for example) than the length thereof in the direction along the longer side, and therefore, even when a misalignment occurs in the direction along the shorter side, the stable electrical connection can be maintained.

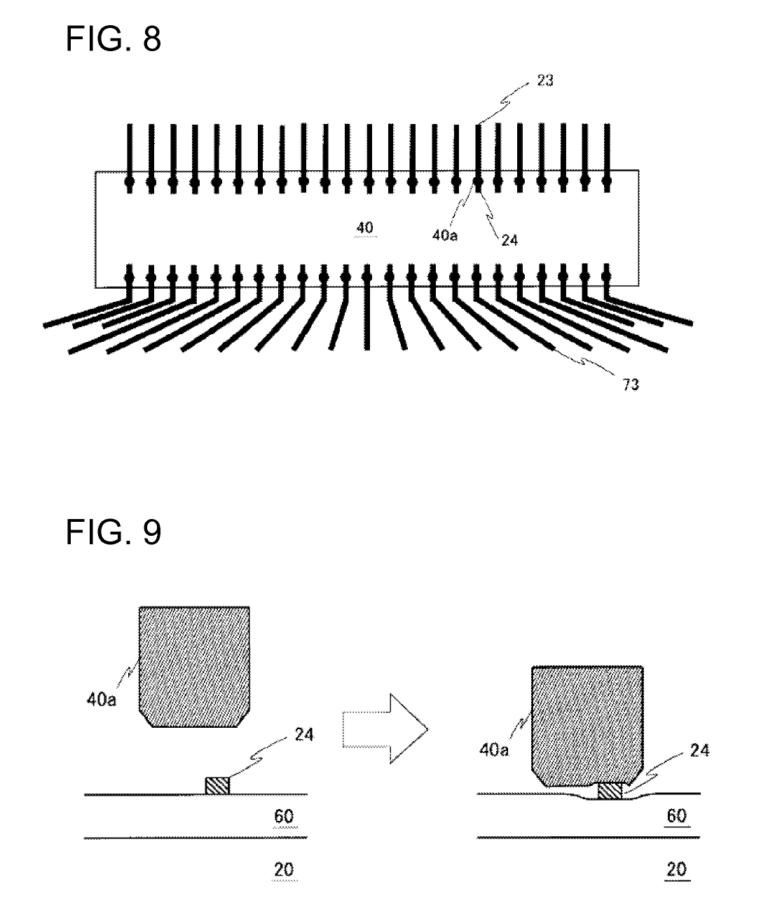

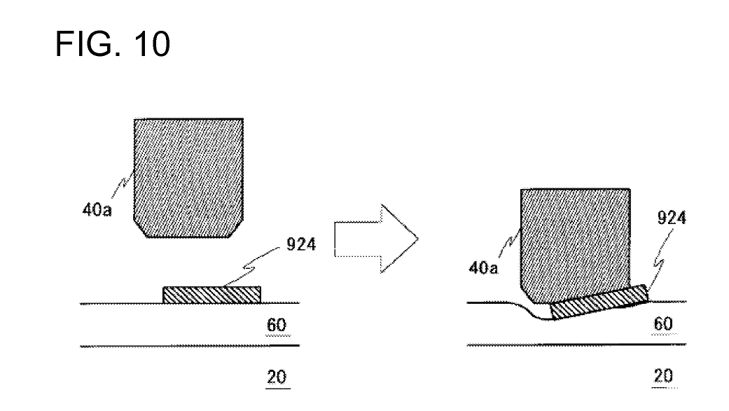

Also, when the terminals 24 are formed this way, even if the LSI chip 40 is misaligned by a small distance (that is, within the area of the above-mentioned cross-section of the bump electrode 40a) in a direction along the longer side of the LSI chip 40 when mounted on the glass substrate 20, the electrical connection is not affected. This point will be described in detail with reference to FIGS. 9 and 10.

FIG. 9 is a cross-sectional view from a direction perpendicular to the direction in which the terminals 24 are extended for illustrating an example of the position of the bump electrode relative to the terminal in connecting the two. In the view to the left of the arrow in FIG. 9, the position where the bump electrode 40a is to make contact with the terminal 24 is illustrated so as to slightly offset from an ideal central position in the direction along the longer side of the LSI chip 40, and the view to the right of the arrow in FIG. 9 shows that the bump electrode 40a is connected to the terminal 24 in a desired manner when they make contact with each other. The NCF 81 that is formed in the surrounding area is not illustrated here.

As shown in this FIG. 9, the width of the terminal 24 in a direction perpendicular to the direction in which the terminal 24 is extended (the direction along the longer side of the LSI chip 40, that is, the width along the direction in which the bump electrodes 40a are arranged) is smaller than the width of the bump electrode 40a along the same direction, and when the terminal 24 is within the area of the bump electrode 40a, the terminal 24 is pressed down in a direction perpendicular to the substrate plane without being tilted, and the condition of the electrical connection does not differ from that of when the terminal 24 is at the ideal central position.

On the other hand, when the width of the terminal 24 in the direction perpendicular to the direction in which the terminal 24 is extended (the direction along the longer side of the LSI chip 40, that is, the width along the direction in which the bump electrodes 40a are arranged) is greater than the width of the bump electrode 40a (a portion thereof that is to make contact) along the same direction, the terminal 24 may tilt. FIG. 10 is a cross-sectional view from a direction perpendicular to the direction in which the terminals 24 are extended for illustrating another example of the position of such a bump electrode relative to the terminal in connecting the two.

It is apparent from a comparison between FIG. 10 and FIG. 9, if the width of terminal 24 in the direction perpendicular to the direction in which the terminal 24 is extended is greater than the width of the bump electrode 40a (a portion thereof to make contact) along the same direction, the bump electrode 40a cannot press down the entire surface of the terminal 24, and as a result, the terminal 24 may tilt. When the terminal 24 is tilted and therefore off-balanced, the condition of the electrical connection is deteriorated, which is not preferable. Therefore, it is preferable that the width of the terminal 24 in the direction perpendicular to the direction in which the terminal 24 is extended be smaller than the width of the bump electrode 40a (a portion thereof to make contact) along the same direction.

It is more preferable that the width of the terminal 24 in the direction perpendicular to the direction in which the terminal 24 is extended be no more than half of the width of the bump electrode 40a (a portion thereof to make contact) along the same direction. This way, even when the position of the bump electrode 40a is offset from the ideal central position to the left or to the right by a quarter of the width of the bump electrode 40a each, the bump electrode 40a is able to press down the entire surface of the terminal 24, preventing the terminal 24 from being tilted, and therefore, the desired electrical connection can be maintained.

### 3. Effects

According to the above-mentioned embodiment, the insulating layer 60 having the terminals 24 on the surface is formed throughout the entire surface of the glass substrate 20 including the extended region 20a, but excluding the display section 30, and therefore, the border (outer periphery) portion of the insulating layer 60 does not overlap areas in which the NCFs 81 and 82 are formed (near the LSI chip 40 and the like). Thus, it is possible to prevent the insulating layer 60 from being peeled off from the border by the NCFs 81 and 82, and therefore prevent a breakage of the terminals 24.

Moreover, because the insulating layer 60 is formed directly below the bump electrodes 40a of the LSI chip 40 and the terminals 24 connected thereto, the pressure-bonding between the terminals 24 and the bump electrodes 40a can be maintained by an elasticity of this insulating layer 60, and as a result, a stable electrical connection between the two can be ensured.

### 4. Modification Examples

### 4.1 First Main Modification Example

In the above-mentioned embodiment, the NCFs 81 and 82 containing no conductive particles are used for mounting the LSI chip 40 and the FPC substrate 50 on the glass substrate 20, but alternatively, an ACF or an ACP containing conductive particles may be used.

In this embodiment, a stable electrical connection can be established by the insulating layer 60 having an elasticity, and therefore, there is no need to use commonly-adopted conductive particles having a layered structure in which a resin with a particle size of 3 μm or larger is coated with a metal layer (nickel plating and gold plating are applied, for example). However, depending on a material of the terminal 24, a very thin (nanometer order) high resistance film such as an oxide film and a hydroxide film may be formed on a surface of the terminal 24. In such a case, by using conductive particles capable of breaking through this high resistance film (when the LSI chip 40 is bonded by pressure), the electrical connection between the bump electrode 40a and the terminal 24 can be secured (that is, the connection resistance can be reduced).

For this reason, it is preferable that the conductive particles be hard enough to break through the above-mentioned high resistance film, unlike the conventional conductive particles that are made of resin and a metal layer so as to have an elasticity for preventing bad connections caused by a variation in bump heights or an expansion of the adhesive agent due to moisture absorption. The preferable conductive particles are typically made of metal (such as nickel) alone, and the conductive particles that do not have a layered structure can be manufactured with ease at low cost.

Further, the conductive particle needs to be larger than the thickness of the above-mentioned high resistance film, but if the size is too large, it becomes difficult to break through the high resistance film. Therefore, a particle size of 1 μm or smaller is preferable. Because it is difficult to form a layered-structure for a conductive particle with such a small particle size, it is preferable to adopt the above-mentioned configuration where the conductive particle is made of a metal alone. Below, a configuration for breaking through the high resistance film in a different manner from that of the above-mentioned first main modification example will be discussed.

### 4.2 Second Main Modification Example

First, when the insulating layer 60 is made of a known low resilience material, the bump electrode 40a can break through the above-mentioned high resistance film for the following reasons. The toughness of the high resistance film is lower than the toughness of the terminals 24, and therefore, when the terminal 24 on which the high resistance film is formed is stretched (pulled), the high resistance film is first ruptured. A portion that undergoes a largest tensile stress when the LSI chip 40 is mounted on the glass substrate 20 is the portion that comes in contact with ends (edge sections) of the bump electrode 40a, for example. Therefore, in order to concentrate the tensile stress in these portions, a known low resilience material is used for the insulating layer 60. The low resilience material is a material that has viscoelasticity, which makes its impact resilience significantly smaller than that of common elastic materials. When the insulating layer 60 is made of such a low resilience material, a portion thereof immediately below an area around the center of the bump electrode 40a sinks evenly when the bump electrode 40a is pressed down, and a portion that is not immediately below the bump electrode 40a does not sink, and therefore, the boundary portions, that is, the portions in contact with the ends (edge sections) of the bump electrode 40a, are largely stretched and undergo a large tensile stress. As a result, the high resistance film in contact with the ends (edge sections) of the bump electrode 40a is ruptured, thereby allowing the bump electrodes 40a to break through the high resistance film.

Even when the low resilience material is not used for the insulating layer 60, the portions in contact with the ends (edge sections) of the bump electrode 40a undergo a tensile stress upon mounting the LSI chip 40 on the glass substrate 20, and therefore, the high resistance film may be ruptured. However, by using the low resilience material, it becomes possible to make the rupture occur more reliably and at a larger scale.

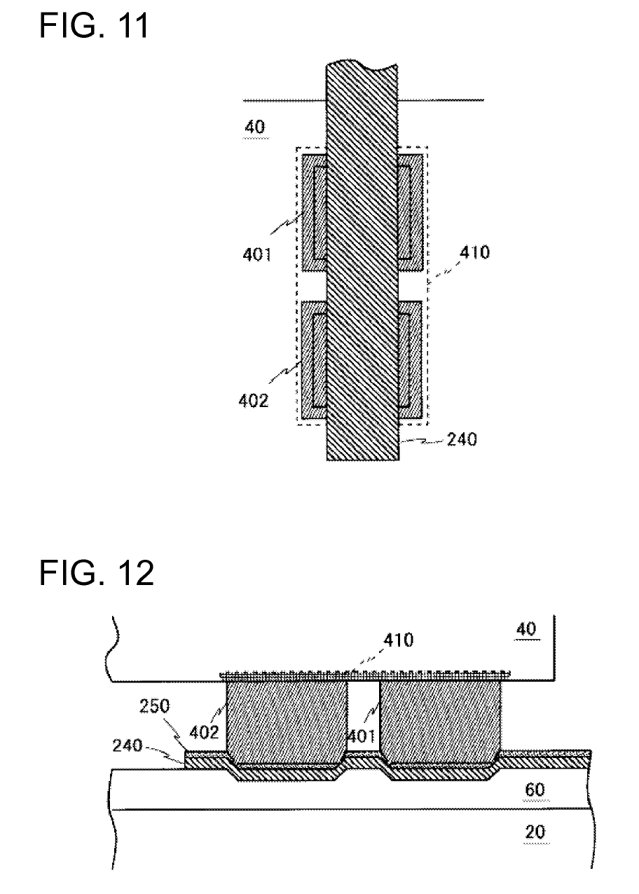

Even when the low resilience material is not used (although it is apparent that it can be used), as the ends (edge sections) of the bump electrode 40a becomes longer, a breakage of the high resistance film occurs at a greater scale (that is, the length of the ruptured portions becomes longer), and this allows the bump electrode 40a to break through the high resistance film in even larger area (at the increased number of places). The configuration of the bump electrode 40a for achieving such an effect will be described with reference to FIGS. 11 and 12.

FIG. 11 is a plan view showing the connection relation between two bump electrodes and one terminal as viewed from a surface on the side opposite to the substrate surface on which the LSI chip 40 is mounted, and FIG. 12 is a cross-sectional view showing the configuration of the two bump electrodes and one terminal shown in FIG. 11. Here, the terminal 240 shown in FIG. 11 corresponds to one of the terminals 24 connected to the display wire 23 shown in FIG. 8. An end of the terminal 240 shown in FIG. 11 is illustrated on the left side of the view in FIG. 12.

As shown in these FIGS. 11 and 12, in this modification example, two bump electrodes 401 and 402 are connected to one terminal 240, and these two bump electrodes 401 and 402 are connected by the same metal electrode layer 410. In FIG. 12, a passivation layer that is formed around an opening of the metal electrode layer, an under barrier metal (UBM) layer that is formed on the metal electrode layer, and the like are not illustrated.

The two bump electrodes 401 and 402 are electrically the same electrode, and are arranged along the direction in which the terminal 240 is extended. Therefore, as compared to the above-mentioned embodiment shown in FIG. 4, for example, the length of the ends (edge sections) of the bump electrodes that are in contact with the terminal 240 becomes twice the length of that of the above-mentioned embodiment. Specifically, as shown in FIG. 12, the high resistance film 250 is ruptured in four places (in the cross-section) at edge sections of the two bump electrodes 401 and 402, and (the edge sections of) the two bump electrodes 401 and 402 are connected to the terminal 240 through the ruptured portions. This makes it possible to secure the electrical connection between the bump electrodes and the terminal (that is, the connection resistance can be reduced).

An example of two bump electrodes 401 and 402 being connected to one terminal 240 was described here, but the bump electrodes to be connected may be three or more, and as long as the to-be-connected bump electrodes are electrically connected, they do not need to be connected by the same metal electrode layer 410. Moreover, a plurality of bump electrodes to be connected to one terminal 240 do not need to be formed for all of the terminals in the liquid crystal panel 10, and a plurality of bump electrodes may only be formed for terminals that are required to have a low resistance such as power terminals and ground terminals. This also applies to other configurations of the bump electrodes and the terminals.

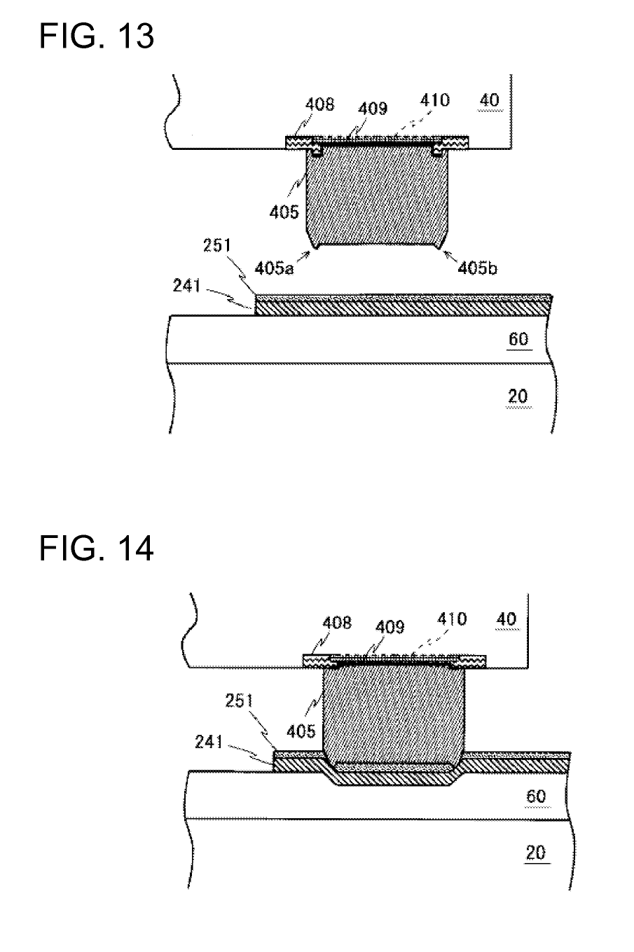

The number of edge sections of the bump electrodes may be increased by forming recesses or protrusions, i.e., grooves, on a surface of the respective bump electrodes, instead of increasing the number of bump electrodes to be connected to one terminal as described above. The recesses or protrusions, i.e., grooves, for example, do not need to be formed so as to be extended along the substrate plane in a direction perpendicular to the direction in which the terminal 240 is extended, and there is no special limitation on the length, shape and the like of the recesses or protrusions. Next, as a modification example in which a protrusion is formed on a surface of the bump electrode, a configuration of the bump electrode having protrusions on the edge sections thereof is described with reference to FIGS. 13 and 14. Forming protrusions in edge sections does not necessarily increase the number of edge sections, but with the edge sections having protrusions, it becomes possible to rupture the high resistance film more reliably.

FIG. 13 is a cross-sectional view showing a configuration of an area near a terminal and a bump electrode having protrusions on the edge sections thereof before the bump electrode is connected to the terminal. FIG. 14 is a cross-sectional view showing the configuration of the area near the bump electrode and the terminal after the bump electrode is connected to the terminal.

As shown in FIG. 13, a passivation layer 408 that is formed in the periphery of an opening of the metal electrode layer 410, which is formed so as to expose the metal electrode layer 410, is also formed on the metal electrode layer 410. Thereafter, an under barrier metal (UBM) layer 409 is formed by sputtering or the like, and a bump electrode 405 is further formed by a plating method or the like. These steps are known, and therefore, the detail explanation thereof is omitted.

In the bump electrode 405 that is formed by such steps, protruding portions 405a and 405b are formed in the edge section thereof, corresponding to the thickness of the passivation layer 408 formed on the metal electrode layer 410 in the periphery of the opening. Because these protruding portions 405a and 405b prevent a contact surface of the bump electrode to the terminal from being planarized, the formation of such protruding portions is generally avoided in the conventional art. However, in this modification example, no preventive measure is adopted, and the passivation layer 408 is intentionally made thicker than usual in order to ensure that the protruding portions 405a and 405b are formed. Specifically, it is preferable that the thickness of this passivation layer 408 be large enough to make the protruding portions 405a and 405b that can break through a very thin high resistance film 251, and be small enough to avoid a cutoff (breakage) of the terminal 241 having a prescribed thickness.

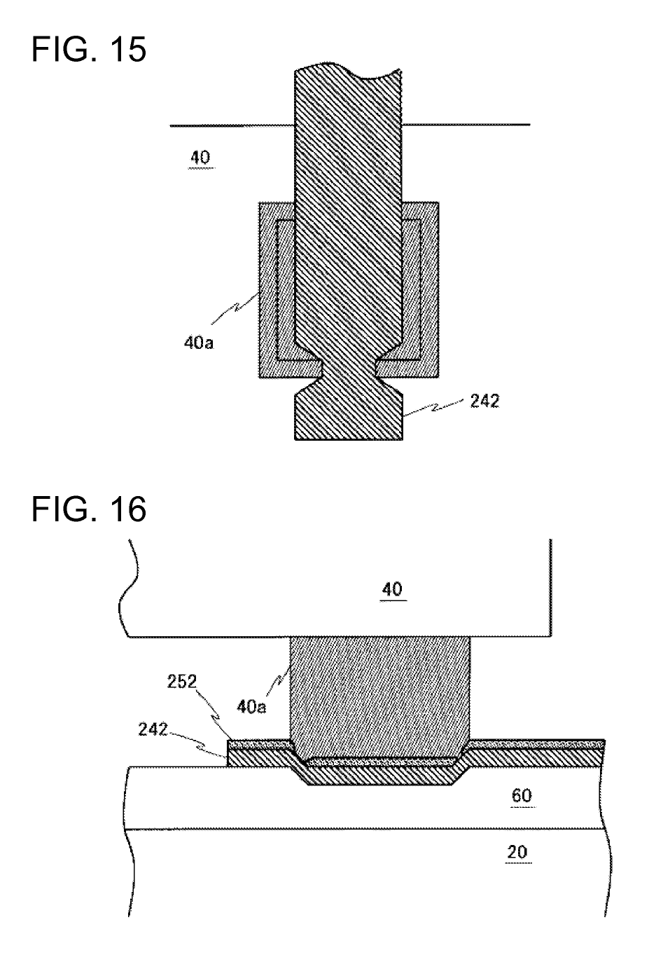

As shown in FIG. 14, by forming the bump electrode 405 in the manner described above, the high resistance film 251 formed on the terminal 241 is ruptured by the protruding portions 405a and 405b of the bump electrode 405, and (the protruding portions of) the two bump electrodes 401 and 402 are connected to the terminal 240 through the ruptured areas. Therefore, it is possible to secure the electrical connection between the bump electrode and the terminal (that is, the connection resistance can be reduced). Next, as a modification example different from the above-mentioned modification examples, a configuration of a terminal that is formed such that the high resistance film is ruptured with ease is described with reference to FIGS. 15 to 20.

FIG. 15 is a plan view showing a shape of the terminal when viewed from a surface on the side opposite to the substrate surface on which the LSI chip 40 is mounted, and FIG. 16 is a cross-sectional view of the electrode and the terminal shown in FIG. 15. Here, a terminal 242 shown in FIG. 15 corresponds to one of the terminals 24 connected to the display wire 23 shown in FIG. 8. An end of the terminal 242 shown in FIG. 15 is illustrated on the left side of the view in FIG. 16.

As shown in FIG. 15, in the terminal 242, among the portions in contact with the edge sections of the bump electrode 40a, a portion near the end of the terminal (lower side of the figure) is made narrower than the other portions, i.e., the terminal 242 is formed to have a neck-shaped portion. When the width of the terminal 242 is made small in this manner, the strength becomes small, and therefore, that portion becomes likely to crack.

Particularly, in the configuration in which a portion with a smaller width is formed between two portions with larger widths in the terminal (that is, having a neck shape), a tensile stress is concentrated in the portion with a smaller width when the LSI chip 40 is mounted, and therefore, the portion is more likely to crack.

When (the bump electrode 40a of) the LSI chip 40 is connected to the terminal having such a configuration, a large tensile stress is concentrated on the portions of the terminal that come in contact with the ends (edge sections) of the bump electrode 40a, and therefore, these portions are cracked. If these portions are cracked, the high resistance film 242, which has a lower toughness than that of the terminal 242, ruptures in a large area (or ruptures in many places). This allows the bump electrode 40a to break through the high resistance film, thereby ensuring the electrical connection between the bump electrode and the terminal (that is, the connection resistance can be reduced).

Further, as shown in FIG. 15, it is preferable that the portion with a smaller width (neck portion) be, between two portions of the terminal in contact with the ends (edge sections) of the bump electrode 40a, the portion close to the end of the terminal in the extending direction, that is, the portion on the side opposite to the side connected to the display wire 23 in which an electrical signal flows. This is because a large tensile stress is applied to the portion of the terminal that come in contact with the ends (edge sections) of the bump electrode 40a, and this stress may not only rupture the high resistance film but also rupture the terminal itself in an actual device due to a variation in heights of the bump electrodes 40a and the like. However, even if the portion of the terminal 242 on the side opposite to the side connected to the display wire 23 is ruptured, it would not affect the electrical connection between the bump electrode and the terminal (that is, it would not increase the connection resistance), thereby causing no problem.

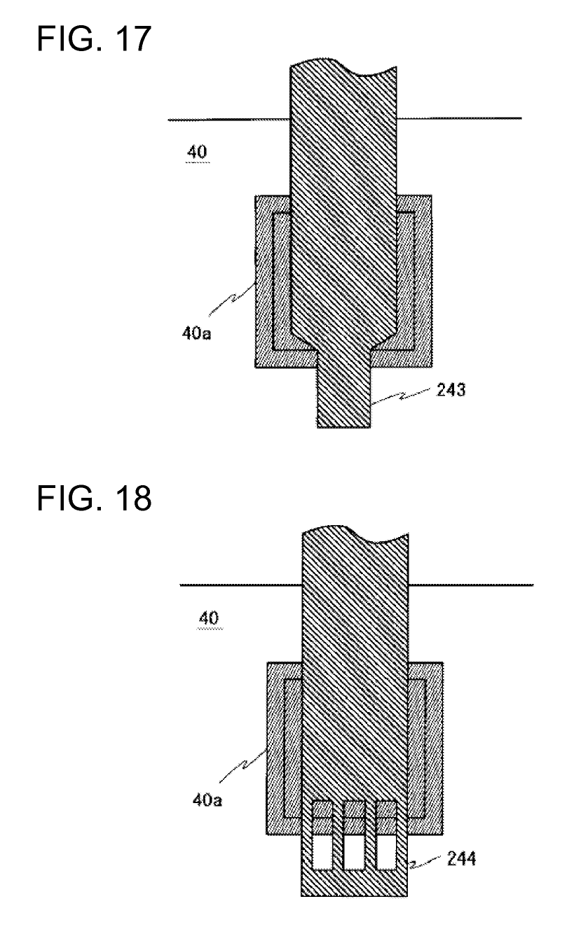

The portion with a smaller width in the terminal does not necessarily need to be formed between two portions with a larger width as shown in FIG. 15 (that is, formed as a neck portion), and as shown in the terminal 243 in FIG. 17, the terminal 243 may be formed such that the width thereof from the end of the terminal to the portion that makes contact with an edge section of the bump electrode 40a becomes smaller than the width of the other portions. Such a configuration can also reduce the strength of the portion with the smaller width. Therefore, although a tensile stress is not concentrated as much as in the configuration shown in FIG. 15, the terminal is more likely to crack and the high resistance film can thereby be ruptured.

In the portion with the smaller width of the terminal, a total width of a metal portion (in a direction perpendicular to the extending direction of the terminal) that serves as a terminal needs to be smaller than other portions. Therefore, as in the terminal 244 in FIG. 18, slits may be formed near the portion in contact with an edge section of the bump electrode 40a on the side closer to the end of the terminal 244 so that (a total width of) the width of the portion becomes smaller than the width of the other portions. In this configuration, the portion with the smaller width is formed between two wider portions in the terminal, and therefore, a tensile stress that is generated when the LSI chip 40 is mounted is concentrated on the portion with the smaller width in a manner similar to the configuration shown in FIG. 15, which makes the portion more likely to crack.

Further, the slits shown in FIG. 18 may be extended to the end portion of the terminal 244 (that is, the end portion becomes a stripe-shape) so that the width of the terminal from the end of thereof to the portion that makes contact with an edge section of the bump electrode 40a becomes smaller than the width of the other portions.

In the portion with the smaller width of the terminal, the strength thereof needs to be reduced, and therefore, in order to reduce the strength, the thickness (length in a direction perpendicular to the substrate plane) of the terminal in that portion may be reduced even though this increases the number of processing steps. The terminal may be provided with a cut so as to form a recess in the thickness direction, for example.

In the examples shown in FIGS. 15 to 17, the width of the terminal is smaller than the width of the bump electrode, and therefore, two of the edge sections of the bump electrode 40a in a direction perpendicular to (along the substrate plane) the extending direction of the terminal (hereinafter referred to as horizontal edge sections) do not make contact with the terminal (in principle). Alternatively, it can be configured such that at least one of the horizontal edge sections can make contact with the terminal, that is, the width of the terminal can be made greater than the width of the bump electrode, for example.

In such a configuration, unlike the above-mentioned configurations shown in FIGS. 15 to 18, the number of portions that make contact with the edge sections of the bump electrode 40a (that has a square shape along the substrate plane) becomes four at a maximum. As described above, however, the portions of the terminal that make contact with the ends (edge sections) of the bump electrode 40a undergo a high tensile stress, which may cause the terminal itself to be ruptured. Therefore, it is preferable the terminal be configured such that a portion thereof connected to the display wire 23 is not ruptured.

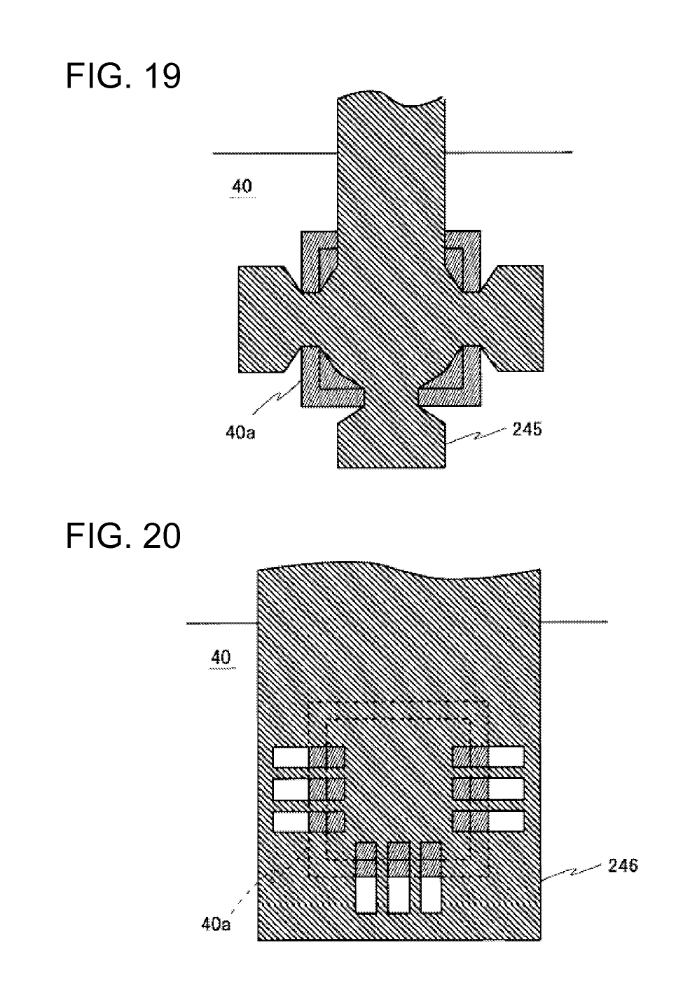

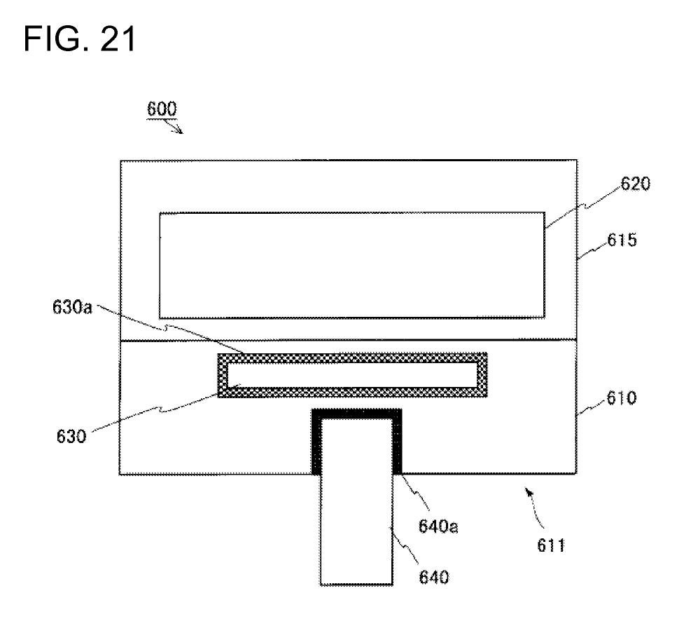

For this reason, as shown in FIG. 19, the terminal may be configured such that, among the four portions of the terminal that makes contact with the ends (edge sections) of the bump electrode 40a, the width of the portion near the end of the terminal and the widths (that is, the length in the extending direction of the terminal) of the portions of the terminal in contact with the horizontal edge sections are made smaller (typically, neck-shaped) than the width of the other portions. One or two of the above-mentioned three portions may not need to have the smaller width.

Here, unlike the example shown in FIG. 19, if the shape of the surface (that is in contact with the terminal) of the bump electrode 40a is rectangular that is longer in the extending direction of the terminal, the width of the portions of the terminal (length in the extending direction of the terminal), which are in contact with the horizontal edge sections, may become greater than the width of the terminal itself. In this case, the “width of the other portions” described above does not refer to the width (length in a direction perpendicular to the extending direction of the terminal along the substrate plane) of the terminal itself. Instead, it refers to a length of a portion of the terminal that is in contact with the bump electrode 40a in a direction parallel with an extending direction of the edge sections, i.e., a length of the longest line segment that can be obtained by cutting the portion of the terminal that is in contact with the bump electrode 40a along lines that are parallel with the extending direction of the corresponding edge section. This way, it can be said that the portions of the terminal extending outwardly from the corresponding edge sections are narrower (in the direction extending outwardly) (typically, neck-shaped).

As shown in FIG. 20, the terminal 246 may be formed such that the width thereof becomes greater than the width of the bump electrode 40a, and may have slits formed in the following portions among the four portions of the terminal that come in contact with the ends (edge sections) of the bump electrode 40a in a manner similar to the configuration shown in FIG. 18: the portion near the end of the terminal; and the portions in contact with the horizontal edge sections so that the width of the portion near the end and the widths (that is, the lengths in the extending direction of the terminal) of the portions in contact with the horizontal edge sections become smaller than the width of the other portion. Here, among the slits formed in the three portions with a smaller width, the slits formed in one or two of the portions may be omitted.

Further, in the configuration where the portion of the terminal extending outwardly from the edge section of the bump electrode 40a is made narrower (typically, neck-shaped) near the edge section (in the direction extending outwardly), the width of the terminal in contact with the edge section of the bump electrode 40a does not have to be smaller than the length of the edge section as long as the width of the terminal is made smaller near the contact area. In the examples shown in FIGS. 15, 17, and 19, for example, even when the bump electrode 40a is smaller than the terminal, i.e., when the length of the edge sections of the bump electrode 40a is smaller than the length of the portion of the terminal that is made narrower (in parallel with the edge section), the narrower portion near the edge sections of the bump electrode 40a becomes structurally weak and is likely to crack, and therefore, the high resistance film near that portion can be ruptured. Even when the slits are formed near the edge section of the bump electrode 40a, i.e., even when an innermost end of the slits is located at a position slightly away from the edge section in the outward direction, unlike the examples shown in FIG. 18 and FIG. 20 where the slits are formed on the edge section, the portion with the slits and hence the smaller width becomes structurally weak, and is likely to crack, which causes the high resistance film near that portion to be ruptured. As described above, the terminal needs to include a portion in which the length thereof parallel to the extending direction of the portion is made smaller, that is, narrower (typically, neck shaped) (than the length of other portions near the portion in a direction parallel to the extending direction) near at least one of the portions that make contact with the edge sections of the bump electrode 40a. This way, the portion becomes more likely to crack and thereby rapture the high resistance film near the portion.

In addition to the above-mentioned configurations, the number of portions where the high resistance film is raptured can be increased by forming a large number of protrusions on a surface of the insulating layer 60. Such a configuration can be readily achieved by forming the insulating layer 60 having a large number of protrusions by a known photolithography, or forming a large number of protrusions by a known ashing process after the insulating layer 60 is formed, for example.

A terminal is formed on such an insulating layer 60 having a large number of protrusions, and therefore, on a surface of the terminal, a large number of protrusions similar to the above-mentioned large number of protrusions are formed. When the bump electrode 40a is pressure-bonded to such a terminal having the large number of protrusions, a high resistance film formed on the terminal is ruptured by the stress concentrated on the tips of the protrusions. Accordingly, the bump electrode 40a breaks through the high resistance film, thereby ensuring the electrical connection between the bump electrode and the terminal (that is, the connection resistance can be reduced).

### 4.3 Other Modification Examples

In the above-mentioned embodiments, the NCF 81 for bonding the LSI chip 40 was different from the NCF 82 for bonding the FPC substrate 50, but the same NCF may be used. Traditionally, an ACF for connecting an LSI chip is often different from an ACF for connecting a FPC substrate. This is because the hardness, the size of a conductive particle, the density of conductive particles and the like of ACFs suitable for the respective connections are different from one another. In this configuration, the LSI chip and the FPC substrate needed to be formed with a prescribed distance therebetween in consideration of the attachment accuracy of the ACFs. However, when the same NCF is used as described above, there is no need to take into account the attachment accuracy, and therefore, it is possible to form the LSI chip and the FPC substrate closer to each other than the above-mentioned distance. This allows the frame area of the display panel to be made narrower, and by using one king of adhesive agent, the manufacturing steps can be simplified. Further, even when an adhesive agent other than the NCF is used, the LSI chip and the FPC substrate can be formed closely by using the same kind of adhesive agent, and therefore, the same effects can be achieved.

In the above-mentioned embodiments, the display wire 23 and the FPC wire 73 are formed below the insulating layer 60, but they may be formed on the insulating layer 60. This eliminates a need of the contact holes for connecting these wires to the terminals. However, in a typical manufacturing process of a liquid crystal display device, an insulating layer such as an interlayer insulating film or a passivation layer is formed after the wiring pattern is formed on a glass substrate as in the above-mentioned embodiment, and therefore, the configuration of the above-mentioned embodiment that can adopt the typical manufacturing process results in a lower manufacturing cost.

The display panel that has been described in the above-mentioned embodiment was a liquid crystal panel, but the present invention is not limited to a liquid crystal panel used in a liquid crystal display device. The present invention can be applied to a display panel used in various display devices such as organic or inorganic EL (Electro Luminescence) displays, plasma display panels (PDP), vacuum fluorescent displays, and electronic papers in a manner similar to the embodiment above. The present invention can also be applied to various display panels that are used in a device other than a display device. Further, the present invention can be applied to various device substrates other than display panels (such as printed circuit boards provided with various electronic parts).

### INDUSTRIAL APPLICABILITY

The present invention is applied to device substrates such as liquid crystal display panels, for example, and is suitable for device substrates including a terminal that is pressure-bonded to a terminal of an electronic part such as an LSI chip mounted using an adhesive agent.

### DESCRIPTION OF REFERENCE CHARACTERS

10 liquid crystal panel
20, 25 glass substrate
20a extended region
23 display wire
24, 240 to 246 terminal
30 display unit
40 LSI chip
40a, 401, 402, 405 bump electrode
50 FPC substrate
60 insulating layer
73 FPC wire
74 wiring layer of FPC substrate
81, 82 NCF (non-conductive film)
250 to 252 high resistance film
408 passivation layer

1. A device substrate mounting an electronic part thereon, comprising:
an insulating substrate;
an insulating layer having a plurality of terminals to be connected to said electronic part formed thereon, the insulating layer being provided continuously between all of said plurality of terminals and said substrate, and having a prescribed elasticity; and
an adhesive agent disposed in a prescribed area that includes an area between said insulating layer and said electronic part,
wherein an outer peripheral portion of said insulating layer is disposed outside of said prescribed area in which said adhesive agent is disposed.

2. The device substrate according to claim 1, further comprising:
a plurality of wires on said substrate, the plurality of wires being connected to said plurality of terminals,
wherein a plurality of contact holes are formed in said insulating layer to connect said plurality of terminals and said plurality of wires, respectively.

3. The device substrate according to claim 2, wherein said plurality of contact holes are formed in said prescribed area in which said adhesive agent is formed.

4. The device substrate according to claim 2, wherein the plurality of contact holes are respectively formed at positions that are remote from the terminals such that a sag of said plurality of terminals in a direction perpendicular to said substrate plane, which occurs in mounting said electronic part, does not cause a connection problem between a corresponding terminal and a corresponding wire.

5. The device substrate according to claim 1, wherein said plurality of terminals are made of a material having a toughness that can prevent the terminals from being broken due to a sag of said plurality of terminals in the direction perpendicular to said substrate plane, which occurs in mounting said electronic part.

6. The device substrate according to claim 5, wherein said plurality of terminals are made of a material containing aluminum or an aluminum alloy.

7. The device substrate according to claim 1, wherein the plurality of terminals are narrower than a plurality of electrodes, respectively, which are formed in said electronic part so as to be connected to the terminals, in an arrangement direction of said plurality of electrodes, and are respectively longer than said plurality of electrodes in a direction perpendicular to said arrangement direction.

8. The device substrate according to claim 7, wherein a width of the respective plurality of terminals in said arrangement direction is smaller than half a width of the respective plurality of electrodes in said arrangement direction.

9. The device substrate according to claim 1, wherein said adhesive agent is a non-conductive film or a non-conductive paste.

10. The device substrate according to claim 1, wherein said adhesive agent contains a conductive particle, and
wherein said conductive particle has a hardness that is sufficient to break through a high resistance film, which may be formed on said plurality of terminals, by a pressure applied in mounting said electronic part.

11. The device substrate according to claim 10, wherein said conductive particle is made of a single material having said hardness.

12. The device substrate according to claim 10, wherein said conductive particle has a particle size of 1 micrometer or smaller.

13. The device substrate according to claim 1, wherein said insulating layer has a portion that protrudes in a direction perpendicular to a plane of said substrate in each of areas that include one or two or more adjacent terminals among said plurality of terminals.

14. The device substrate according to claim 13, wherein said insulating layer is formed so as to protrude in the direction perpendicular to said plane of said substrate in each of said terminals.

15. The device substrate according to claim 13, wherein the insulating layer has a plurality of protrusions that protrude in the direction perpendicular to said plane of said substrate on a surface that makes contact with said plurality of terminals.

16. The device substrate according to claim 1, wherein said electronic part includes a plurality of electrodes to be connected to said plurality of terminals, and
wherein said insulating layer is made of a material having a low resilience so that stress is concentrated on portions of said plurality of terminals, which are to be in contact with edge sections of said plurality of electrodes in mounting said electronic part.

17. The device substrate according to claim 1, wherein said electronic part includes a plurality of electrodes to be connected to said plurality of terminals, and
wherein, of said plurality of electrodes that constitute respective groups of electrodes, at least a plurality of electrodes constituting one group are respectively connected to one corresponding terminal along an extending direction of said terminal.

18. The device substrate according to claim 1, wherein said electronic part includes a plurality of electrodes to be connected to said plurality of terminals, and
wherein prescribed recesses or protrusions are respectively formed on respective faces of said plurality of electrodes to be in contact with said plurality of terminals so as to break through a high resistance film that may be formed on said plurality of terminals.

19. The device substrate according to claim 18, wherein said electronic part is an integrated circuit module, and includes a plurality of bump electrodes, which correspond to said plurality of electrodes, and
wherein, in order to form, on said respective faces of said plurality of bump electrodes, protrusions having a height that is sufficient to break through the high resistance film that may be formed on said plurality of terminals, a pattern of a passivation film is formed below the bump electrode in said electronic part and a thickness of the passivation layer formed on a surface facing said faces is made substantially the same as said height.

20. The device substrate according to claim 1, wherein said electronic part includes a plurality of electrodes to be connected to said plurality of terminals, and
wherein the respective plurality of terminals include, near at least one of portions to be in contact with edge sections of respective one of said plurality of electrodes that are to be connected in mounting said electronic part, portions that are made narrower in a direction parallel to an extending direction of said portion terminals.

21. The device substrate according to claim 20, wherein the respective plurality of terminals have slits formed in the portions that are made narrower.

22. The device substrate according to claim 20, wherein a plurality of wires respectively connected to said plurality of terminals are formed on said substrate, and
wherein each of the plurality of terminals has said portion that is made narrower near at least one of portions to be in contact with said edge sections, except at a portion closest to a corresponding wire of said plurality of wires.

23. The device substrate according to claim 22, wherein each of the plurality of terminals has said portion that is made narrower near a portion closest to an end of said terminal among portions to be in contact with said edge sections.

24. The device substrate according to claim 1, wherein said substrate includes a display section that displays an image, and
wherein said electronic part includes a driver element that drives said display section in accordance with a signal given from an outside.

25. The device substrate according to claim 24, wherein said display section comprises:
a light reflective unit that reflects light incident from the outside; and
a liquid crystal layer that controls transmittance of light incident from the outside and light reflected by said reflective unit, and
wherein said light reflective unit is formed of a same material as a material of said terminals.

26. The device substrate according to claim 1, wherein said electronic part includes an integrated circuit chip and a flexible substrate, and
wherein a same kind of said adhesive agent is formed between said insulating layer and said integrated circuit chip, and between said insulating layer and said flexible substrate.

27. A method for manufacturing a device substrate in which mounting an electronic part thereon is mounted on a substrate by a non conductive adhesive agent, the method comprising:
an insulating layer formation step of forming an insulating layer having a prescribed elasticity on an insulating substrate;
a terminal formation step of forming a plurality of terminals to be connected to said electronic part on said insulating layer;
a bonding preparatory step of forming an adhesive agent in a prescribed area that includes an area between said insulating layer and said electronic part; and
a mounting step of mounting said electronic part by pressure-bonding said electronic part to said substrate using a prescribed pressure-bonding method,
wherein, in the insulating layer formation step, said insulating layer is continuously provided between all of said plurality of terminals and said substrate, and an outer peripheral portion of said insulating layer is formed outside of said prescribed area in which said adhesive agent is formed.

28. The method for manufacturing a device substrate according to claim 27, further comprising:
a pattern formation step of forming a conductive pattern that becomes a plurality of wires to be respectively connected to said plurality of terminals on said substrate; and
a contact hole formation step of forming contact holes for connecting said plurality of terminals to said plurality of wires in said insulating layer.

29. The method for manufacturing a device substrate according to claim 27, further comprising:
a display section formation step of forming, on said substrate, a display section that displays an image,
wherein, in the terminal formation step, said terminals are formed by using a same method as a film formation method that is to be used when a light reflective unit for reflecting incident light from the outside is formed in said display unit, and by using a same material as a material to be used for said light reflective unit.
